(19) United States
(12) Patent Application Publication
(10) Pub. No.: US 2012/0235282 A1
(43) Pub. Date: Sep. 20, 2012

(54) SEMICONDUCTOR DEVICE MANUFACTURING METHOD AND SEMICONDUCTOR DEVICE

(75) Inventors: Akira TOMONO, Kawasaki-shi (JP); Tetsuya KUROSAWA, Yokohama-shi (JP); Tsutomu FUJITA, Yokkaichi-shi (JP); Mika KIRITANI, Kawasaki-shi (JP); Shinya TAKYU, Minami-Saitama-gun (JP)

(73) Assignee: KABUSHIKI KAISHA TOSHIBA, Tokyo (JP)

(21) Appl. No.: 13/372,962

(22) Filed: Feb. 14, 2012

(30) Foreign Application Priority Data
Mar. 15, 2011 (JP) 2011-057233

(51) Int. Cl. H01L 21/78; H01L 23/00

(52) U.S. Cl. 257/618; 438/462; 257/E21.599; 257/E23.194

(57) ABSTRACT

According to one embodiment, a semiconductor device manufacturing method is disclosed. The method comprises (a) forming cut grooves in a front surface of a semiconductor wafer on which semiconductor elements are formed to partition the front surface into a plurality of regions, (b) disposing partly a resin in the cut grooves, (c) adhering a protection tape on the front surface of the semiconductor wafer, (d) thinning the semiconductor wafer by grinding a rear surface of the semiconductor wafer to reach the cut grooves, (e) forming an adhesive agent layer on the rear surface of the semiconductor wafer, and (f) dividing the semiconductor wafer into a plurality of semiconductor chips by cutting the adhesive agent layer together with the disposed resin along the cut grooves.

### CROSS-REFERENCE TO RELATED APPLICATION

This application is based upon and claims the benefit of priority from the prior Japanese Patent Application No. 2011-057233, filed on Mar. 15, 2011; the entire contents of all of which are incorporated herein by reference.

### FIELD

Embodiments described herein relate to a manufacturing method of a semiconductor device and a semiconductor device.

### BACKGROUND

In recent years, a technique called a dicing-before-grinding process has been used to obtain individual semiconductor chips from a semiconductor wafer having semiconductor elements formed.

According to the dicing-before-grinding process, cut grooves are first formed in a front surface, on which semiconductor elements are formed, of the semiconductor wafer (half-cut dicing). A protection tape is then affixed to the front surface of the semiconductor wafer, and a rear surface of the semiconductor wafer is ground to reach the cut groove portions. Thus, the thickness of the semiconductor wafer is reduced, and the semiconductor wafer is divided or singulated into individual semiconductor chips. Then, an adhesive film (die attach film) is affixed to the rear surface of the semiconductor wafer to form an adhesive agent layer, and the protection tape is separated from the front surface. The adhesive agent layer is then cut from the front surface side of the semiconductor wafer along the dividing grooves by a diamond blade, a laser or the like. As a result, the semiconductor chips each having the adhesive agent layer are obtained. Each of the semiconductor chips is then picked up by an adsorbing tool called a collet, and stacked and bonded on a substrate or another semiconductor chip.

According to the above method, the semiconductor wafer is divided into the individual semiconductor chips in the stage where the rear surface of the semiconductor wafer has been ground, and the alignment of the semiconductor chips is disordered. Therefore, if the adhesive film is cut, there is a possibility that a wire portion of the element may be cut partly, the surface may be contaminated by cut dust, or a crack may be caused in the semiconductor chip when it is picked up after cutting because of a load applied at the time of cutting or thermal fusion bonding.

### BRIEF DESCRIPTION OF DRAWINGS

FIG. 1 is a schematic perspective view showing a manufacturing step of the semiconductor device according to an embodiment.

FIG. 2 is a schematic perspective view showing a step after the step in FIG. 1.

FIG. 3 is a schematic perspective view showing a step after the step in FIG. 2.

FIG. 4 is a schematic perspective view showing a step after the step in FIG. 3.

FIG. 5 is a schematic perspective view showing a step after the step in FIG. 4.

FIG. 6 is a schematic perspective view showing a step after the step in FIG. 5.

FIG. 7 is a schematic perspective view showing a step after the step in FIG. 6.

FIG. 8 is a schematic perspective view showing a step after the step in FIG. 7.

FIG. 9 is a schematic perspective view showing a step after the step in FIG. 8.

FIG. 10A to FIG. 10G are schematic sectional views showing manufacturing steps of the semiconductor device according to the embodiment.

FIG. 11A and FIG. 11B are plan views showing a method of disposing a resin according to the embodiment.

FIG. 12A and FIG. 12B are plan views showing a method of disposing a resin according to another embodiment.

FIG. 13A and FIG. 13B are plan views showing a method of disposing a resin according to another embodiment.

FIG. 14 is a reproduction view of a rear surface of the semiconductor wafer after the step in FIG. 4, which is prepared from a photograph taken through a magnifier.

FIG. 15 is a reproduction view of a rear surface of the semiconductor wafer after performing the step in FIG. 4 without disposing the resin, which is prepared from a photograph taken through a magnifier.

### DETAILED DESCRIPTION

In general, according to one embodiment, a semiconductor device manufacturing method is disclosed. The method includes (a) forming cut grooves in a front surface of a semiconductor wafer on which semiconductor elements are formed to partition the front surface into a plurality of regions, (b) disposing partly a resin in the cut grooves, (c) adhering a protection tape on the front surface of the semiconductor wafer, (d) thinning the semiconductor wafer by grinding a rear surface of the semiconductor wafer to reach the cut grooves, (e) forming an adhesive agent layer on the rear surface of the semiconductor wafer, and (f) dividing the semiconductor wafer into a plurality of semiconductor chips by cutting the adhesive agent layer together with the disposed resin along the cut grooves.

According to another embodiment, a semiconductor device is disclosed. The device includes a semiconductor chip having a rectangular plan shape. The semiconductor chip has a semiconductor element disposed on a front surface thereof and an adhesive agent layer disposed on a rear surface thereof. A part of a side surface of the semiconductor chip is selectively coated with a resin.

Embodiments are described below with reference to the drawings. In the description of the drawings, the same reference numeral is given to the same element or the elements which have the same function, and the overlapped description will be omitted.

### First Embodiment

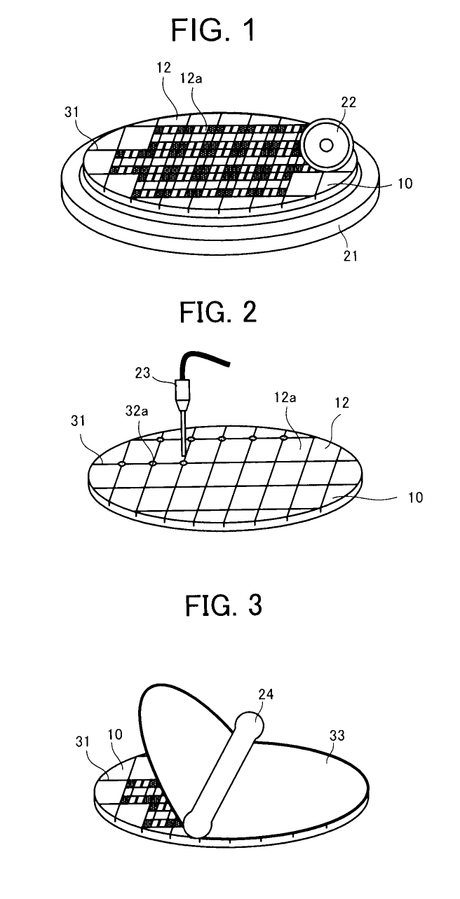

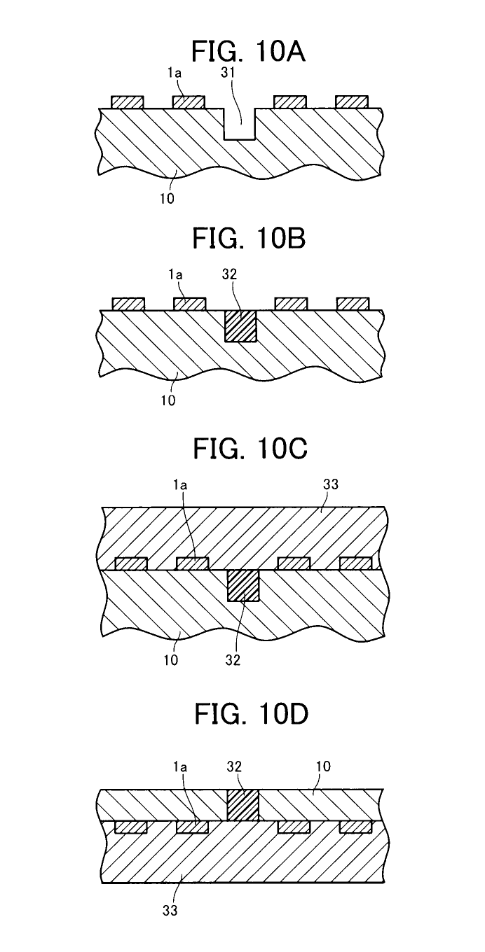

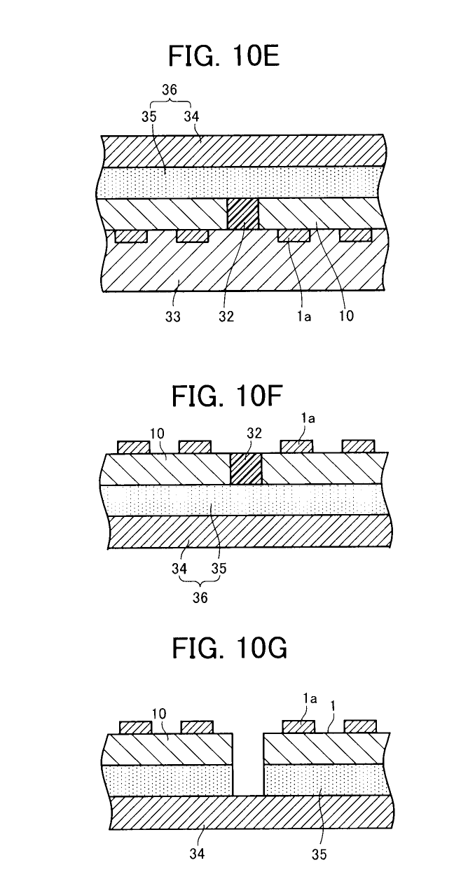

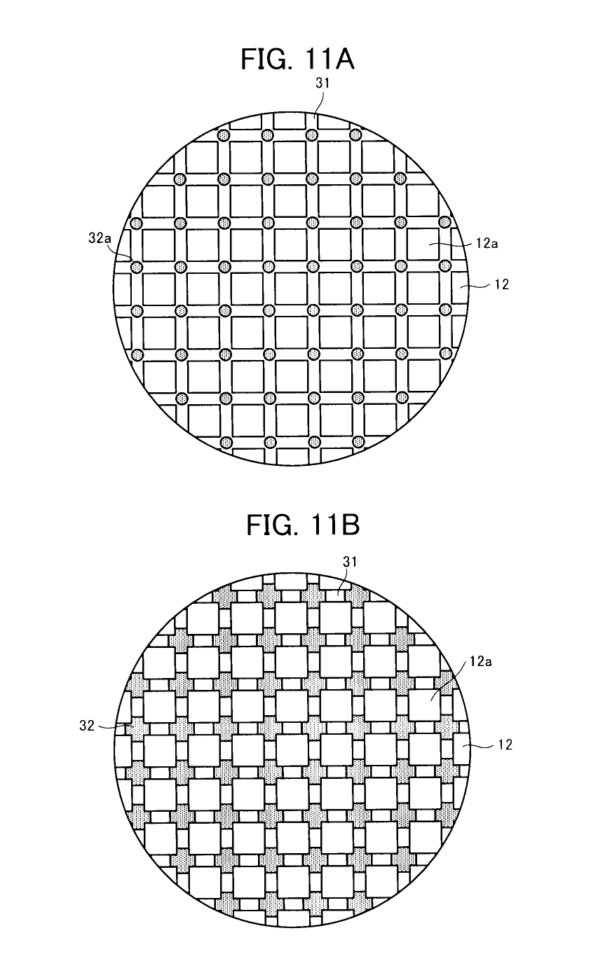

FIG. 1 to FIG. 9 are schematic perspective views showing sequentially the steps of the semiconductor device manufacturing method according to this embodiment, and FIG. 10A to FIG. 10G are schematic sectional views showing sequentially the same steps. FIG. 10A to FIG. 10G show main portions only, and the apparatus, jigs and the like used for manufacturing are omitted.

In the embodiment, semiconductor elements are formed on the front surface of a semiconductor wafer 10 which is formed of silicon or the like. The semiconductor wafer 10, on which the semiconductor elements are formed, is fixed onto a holding table 21, and cut grooves 31 having a grid pattern and a depth not reaching the rear surface are formed from the front surface side of the semiconductor wafer 10 along dicing lines (or chip division lines) by a diamond blade 22 (FIG. 1 and FIG. 10A). That is, half-cut dicing is performed. The diamond blade 22 is not used exclusively to form the cut grooves 31, but a diamond scriber, a laser or the like can also be used. It is also possible to use another means such as reactive gas etching, reactive ion etching (RIE) or the like. When the cut grooves 31 are formed, the front surface of the semiconductor wafer 10 is divided into a plurality of regions 12 including rectangular regions 12a which become semiconductor chips and have the semiconductor elements on the front surfaces. In FIG. 10A, the numeral 1a denotes electrodes protruded from the front surface of the semiconductor wafer 10.

A liquid resin 32a is injected and cured in the cut grooves 31. The liquid resin 32a is injected and cured in such a way that it is partly in the cut grooves 31 and restricts the mutual movement of the adjacent regions 12 by a cured resin 32, namely, that the alignment of the individual regions 12 is not disordered in a subsequent step. In the embodiment, the liquid resin 32a is injected to a substantially center of a position where two cut grooves 31 intersect as shown in FIG. 11A. The injected liquid resin 32a spreads and cures in the cut grooves 31 to cover opposed corners of four regions 12 as shown in FIG. 11B. When the resin 32 is disposed as described above, the mutual movement of the adjacent regions 12 is restricted, and the alignment of the individual regions 12 can be maintained in a subsequent step. In addition, since the resin 32 is disposed partly, shrinkage deformation due to curing can be reduced. Thus, it is possible to prevent the semiconductor wafer 10 from warping and a crack or the like of the semiconductor chip involved in such occurrence as in a case where the resin is disposed to fill the cut grooves 31. That is, when the resin is disposed to fill the cut grooves 31, the shrinkage deformation due to curing of the resin increases. As a result the semiconductor wafer 10 may warp, a large tensile stress may be applied to the semiconductor chip 1, and cracks or the like may occur in the chip. In contrast, when the resin 32 is disposed partly, shrinkage deformation due to curing of the resin is small, and occurrence of a warp in the semiconductor wafer 10 is suppressed. As a result, the tensile stress to the semiconductor chip due to the warp is also suppressed, and cracks or the like in the chip is prevented. In FIG. 2, the numeral 23 denotes an injection nozzle for injecting the liquid resin 32a into the cut grooves 31. The injection nozzle 23 is connected to a resin feeder (not shown).

From the viewpoint of fully maintaining the alignment of the individual regions 12 by appropriately disposing the resin 32 at the required positions of the cut grooves 31 and restricting the mutual movement of the adjacent regions 12, it is preferable that the liquid resin 32a used has a viscosity (at 23° C.) of 4 Pa·s or more, and the cured resin has a modulus of elasticity (at 23° C.) of 0.2-5000 MPa. If at least one of the viscosity (at 23° C.) and the modulus of elasticity (at 23° C.) of the cured resins is not within the above range, the alignment of the individual regions 12 might not be maintained adequately. The viscosity (23° C.) of the liquid resin is more preferably in the range of 9-21 Pas, and still more preferably 15-16 Pa·s. The modulus of elasticity (23° C.) of the cured resin is more preferably in the range of 10-5000 MPa. The modulus of elasticity of the cured resin may be determined in accordance with JIS K 6868-1 (Adhesives—Determination of shear behavior of structural bonds—Part 1 Torsion test method using butt-bonded hollow cylinders). The liquid resin is not limited to a particular type. For example, there can be used a thermosetting resin such as an epoxy-based resin, a silicone-based resin, a polyimide-based resin or a phenol-based resin, and a light curable resin such as an acrylic resin. An epoxy-based resin may be particularly used from viewpoints of mechanical strength, insulation, chemical resistance, water resistance, moisture resistance, etc.

A protection tape 33 is then affixed to the front surface of the semiconductor wafer 10, where the cut grooves 31 are formed and the resin 32 is disposed therein, to form a surface protection layer (FIG. 3 and FIG. 10C). For the protection tape 33, there may be used, for example, a pressure sensitive adhesive tape or the like which has a pressure sensitive adhesive layer formed on a tape base material made of a thermoplastic resin such as polyvinyl chloride resin (PVC), polyethylene terephthalate resin (PET), polyolefin resin (PO) or the like. It is also possible to use one which has a pressure sensitive adhesive layer formed on a base material of glass or the like instead of the protection tape 33. The pressure sensitive adhesive may be a light curable pressure sensitive adhesive. Preferably the pressure sensitive adhesive tape having a light curable pressure sensitive adhesive is used since the protection tape 33 is separated in a later step, which may be easily separated by light irradiation. In FIG. 3, the numeral 24 denotes a holddown member for adhering tightly the protection tape 33 to the front surface of the semiconductor wafer 10.

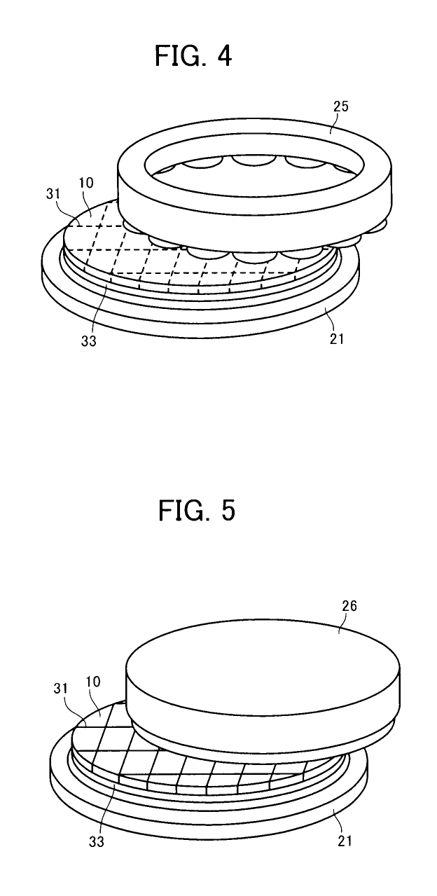

Then, the thickness of the semiconductor wafer 10 is decreased by grinding a rear surface of the semiconductor wafer 10 by a grinding stone 25 to reach the cut grooves 31 (FIG. 4 and FIG. 10D). In this thinning process, an etching may be performed by an etching apparatus 26 after grinding by the grinding stone 25 (FIG. 5). The etching methods include, but not limited to dry etching, plasma etching, and wet etching. Instead of the etching, planarization may be performed by CMP (chemical mechanical polishing). Rear surface chipping can be reduced by performing etching or planarization process after the grinding.

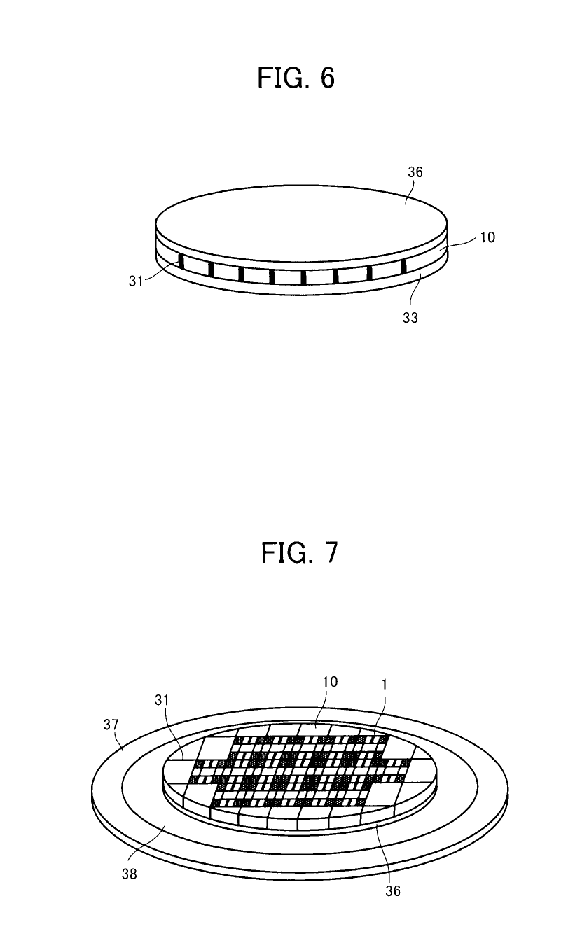

After the rear-surface grinding or after the rear-surface grinding and etching (or planarization), an adhesive film 36 which has an adhesive agent layer 35 formed on a film base material 34 is applied onto the rear surface of the semiconductor wafer 10 with the adhesive agent layer 35 side faced toward the semiconductor wafer 10 (FIG. 6 and FIG. 10E).

Subsequently, the semiconductor wafer 10, to which the adhesive film 36 was affixed, is held on a film 38, which is affixed to a wafer ring 37, with the adhesive film 36 downside and the protection tape 33 upside, and the protection tape 33 is separated (FIG. 7 and FIG. 10F). The film 38 may be one having or not having adherence. The semiconductor wafer 10 may be held directly on the holding table or the like without using the film 38.

To form the adhesive agent layer in the embodiment, the adhesive film 36 having the adhesive agent layer 35 formed on the film base material 34 is used, but an adhesive film formed of the adhesive agent layer 35 only can also be used.

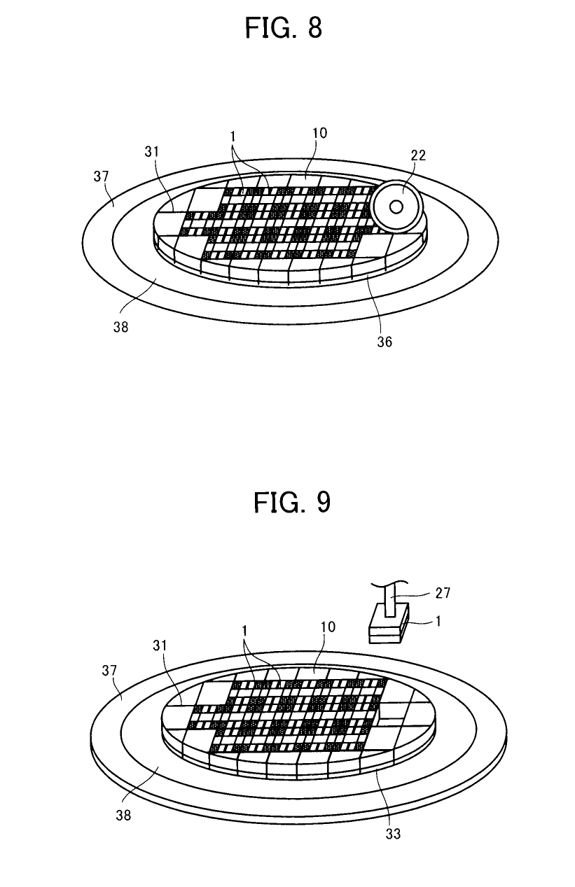

The adhesive agent layer 35 is then cut along dicing lines (or chip division lines) from the front surface side of the semiconductor wafer 10, from which the protection film 33 was separated, by using the diamond blade 22 having the same or little smaller width as or than that of the one used to form the cut grooves 31 (FIG. 8 and FIG. 10G). In the previous step (FIG. 1 and FIG. 10A), the cut grooves 31 are formed along the dicing lines (or chip division lines) in the semiconductor wafer 10, and the resin 32 is partly disposed in the cut grooves 31 to restrict the mutual movement of the adjacent regions 12. Therefore, by cutting along the dicing lines (or chip division lines), the resin 32 in the cut grooves 31 and the adhesive agent layer 35 below the cut grooves 31 are selectively cut by the diamond blade 22. Thus, the semiconductor wafer 10 is divided into plural pieces each including the semiconductor chip 1. Cutting may be performed by a diamond scriber, a laser or the like.

When the diamond blade 22 having a smaller cutting width than that of the one used to form the cut grooves 31 is used or when another cutting means is used to cut with a smaller width than those of the cut grooves 31, cutting is performed with the resin 32 partly remained on the surfaces (corner surfaces in this embodiment) of the individual semiconductor chips 1. Thus, when the resin 32 is partly remained on the surfaces of the semiconductor chips 1, an adhesive property between the semiconductor chips and the mold resin can be enhanced in a case where the semiconductor chips are resin molded in a subsequent step.

The formed semiconductor chip 1 having the adhesive agent layer 35 on the rear surface is picked up by a pickup mechanism provided with an adsorbing collet 27 and conveyed to a predetermined manufacturing step for the semiconductor device, such as a mounting step on a substrate or another semiconductor chip (FIG. 9).

According to this embodiment, after the cut grooves 31 are formed, the liquid resin 32a is injected and cured partly in the cut grooves 31 to restrict the movement of the mutual adjacent regions 12 by the cured resin 32. Therefore, the initial alignment of the individual regions 12 can be maintained until the time when the adhesive agent layer 35 affixed to the rear surface of the semiconductor wafer 10 is cut. Accordingly, the adhesive agent layer 35 affixed to the rear surface of the semiconductor wafer 10 can be cut easily without applying a stress or the like which causes a partial breakage of the wiring portion of the semiconductor element, contamination due to cut dust, or a crack in the chip. As a result, the quality of the manufactured semiconductor device is improved, and the manufacturing yield can be improved.

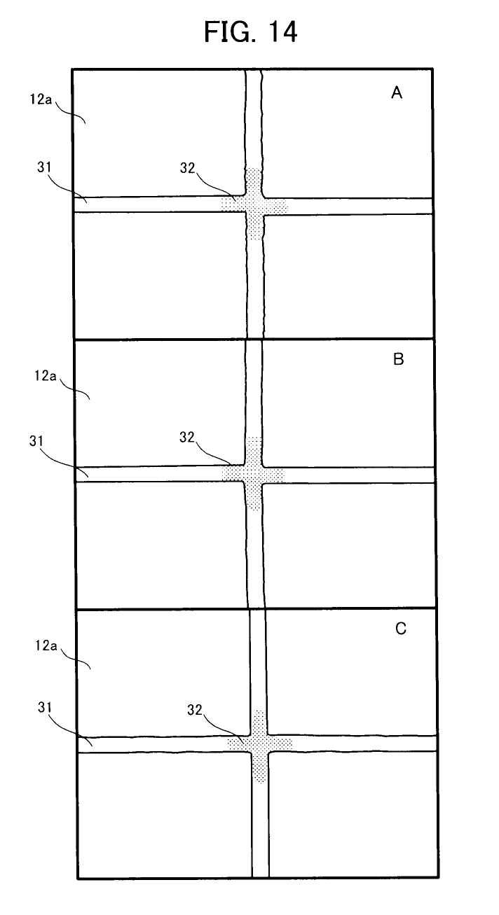

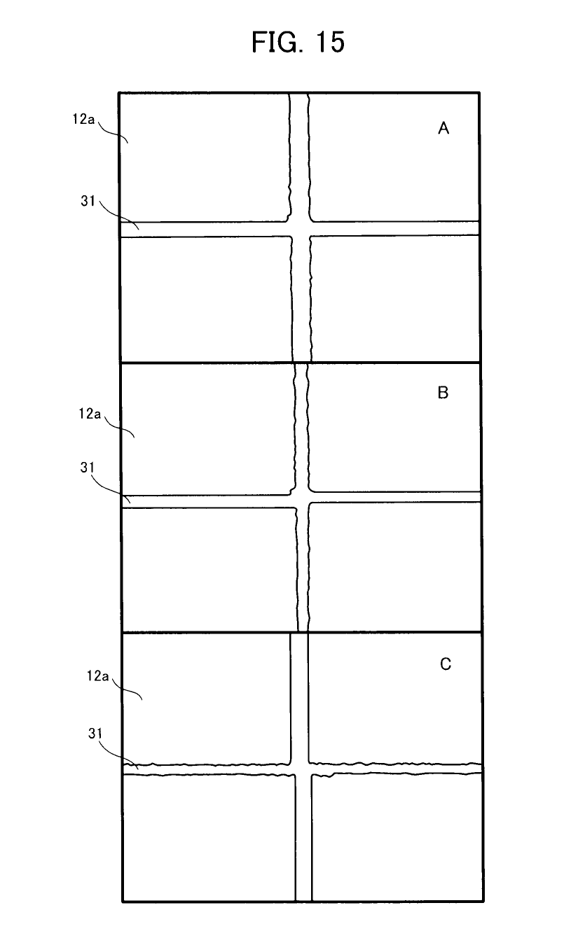

FIG. 14 is a reproduction prepared by selecting three portions (A, B and C) on the periphery from a photograph of a rear surface taken by observing through a magnifier after the thinning process according to the embodiment in order to examine a change in the alignment of the regions 12 formed by dividing the front surface of the semiconductor wafer. And, FIG. 15 is a reproduction prepared for comparison by selecting three portions (A, B and C) on the same periphery as shown in FIG. 4 from a photograph of a rear surface of the semiconductor wafer taken after performing the thinning process without disposing the resin. It is apparent from the above drawings that when the resin is disposed in the cut grooves 31 according to this embodiment, the alignment of the regions 12 is not disordered substantially, but when the thinning process is performed without disposing the resin in the cut grooves 31, the width and positions of the cut grooves 31 are varied, and the alignment of the regions 12 is disordered.

According to this embodiment, since the resin 32 is disposed partly, shrinkage deformation due to curing can be reduced. Thus, it is possible to prevent the semiconductor wafer 10 from warping and a crack or the like of the semiconductor chip 1 involved in such occurrence as in a case where the resin is disposed to fill the cut grooves 31.

### Other Embodiments

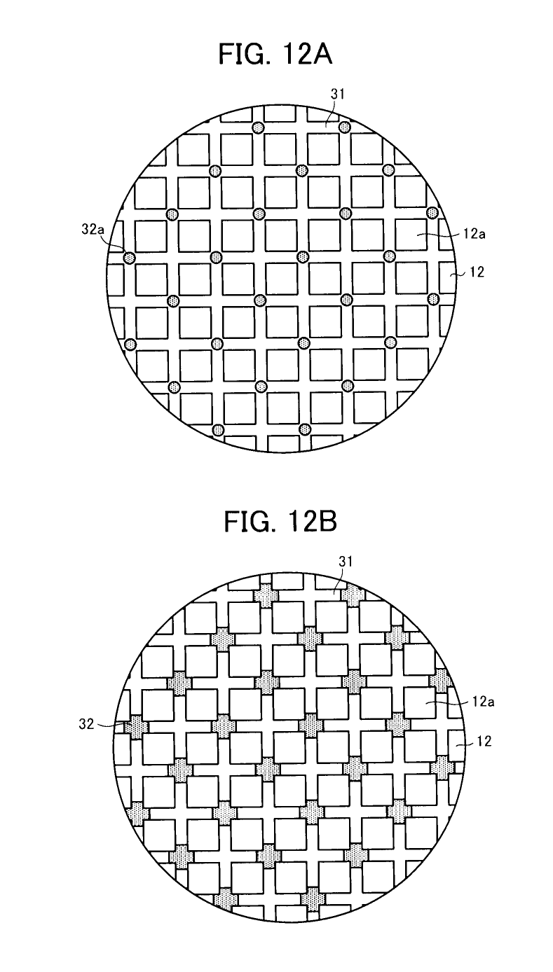

In the first embodiment, it is configured to restrict the mutual movement of the adjacent regions by injecting the liquid resin into all positions where two cut grooves intersect. But, the liquid resin 32a may be injected and cured in every other positions where two cut grooves 31 intersect, namely, the liquid resin 32a may be alternately disposed and not disposed as shown in, for example, FIG. 12A. FIG. 12B is a view schematically showing a state of the cured resin, and the resin 32 is disposed at a pair of diagonally opposite corners of the individual rectangular regions 12a. According to this disposing method, the mutual movement of the adjacent regions 12 can also be restricted in the same manner as in the first embodiment. Since the resin 32 is disposed partly, shrinkage deformation due to curing can be reduced. Thus, it is possible to prevent the semiconductor wafer from warping and a crack or the like of the semiconductor chip 1 involved in such occurrence as in a case where the resin is disposed to fill the cut grooves 31. In addition, according to this method, the injected resin amount and the number of times to inject the resin are small in comparison with the first embodiment. Thus, it is economical, time can be saved, and production efficiency can be improved.

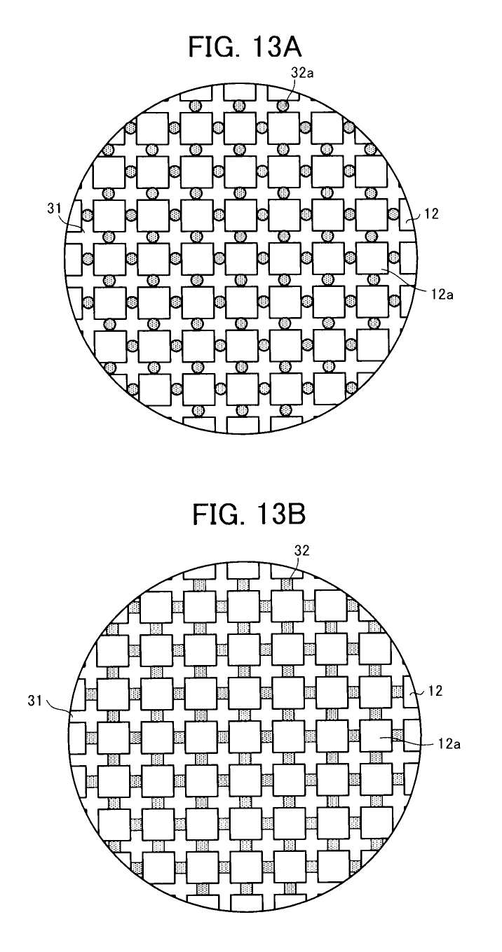

And, for example, the liquid resin 32a may be injected and cured between the adjacent regions 12 or at portions forming the sides of the individual regions 12 as shown in FIG. 13A. FIG. 13B is a view schematically showing a state of the cured resin of the above case. According to this disposing method, the mutual movement of the adjacent regions 12 can also be restricted in the same manner as in the first embodiment. Since the resin 32 is disposed partly, shrinkage deformation due to curing can be reduced. Thus, it is possible to prevent the semiconductor wafer from warping and a crack or the like of the semiconductor chip involved in such occurrence as in a case where the resin is disposed to fill the cut grooves 31.

The resin may be disposed to maintain at least the alignment of the regions which become the semiconductor chips, namely the rectangular regions on which the semiconductor elements are formed, among the regions partitioned by the cut grooves. Therefore, even the methods shown in, for example, FIG. 11A, FIG. 11B, FIG. 12A, FIG. 12B, FIG. 13A and FIG. 13B need not necessarily dispose the resin on the periphery which does not affect on the alignment of the mutual rectangular regions 12a.

According to at least one of the above-described embodiments, the resin is disposed in the cut grooves after the cut grooves were formed to restrict the mutual movement of the adjacent regions, so that the initial alignment of the individual regions is maintained until the time when the adhesive agent layer formed on the rear surface of the semiconductor wafer is cut. Therefore, the adhesive agent layer formed on the rear surface of the semiconductor wafer can be cut easily without applying a stress or the like which causes a partial breakage of the wiring portion of the semiconductor elements, contamination due to cut dust, or a crack in the chips. Thus, the semiconductor device having good quality can be produced in a good yield. Since the resin is disposed partly in the cut grooves, shrinkage deformation due to curing can be reduced. Thus, it is possible to prevent the semiconductor wafer from warping and a crack or the like of the semiconductor chip involved in such occurrence.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method of a semiconductor device, comprising:
(a) forming cut grooves in a front surface of a semiconductor wafer on which semiconductor elements are formed to partition the front surface into a plurality of regions;
(b) disposing partly a resin in the cut grooves;
(c) adhering a protection tape on the front surface of the semiconductor wafer;
(d) thinning the semiconductor wafer by grinding a rear surface of the semiconductor wafer to reach the cut grooves;
(e) forming an adhesive agent layer on the rear surface of the semiconductor wafer; and
(f) dividing the semiconductor wafer into a plurality of semiconductor chips by cutting the adhesive agent layer together with the disposed resin along the cut grooves.

2. The method according to claim 1,
wherein the resin is disposed to restrict the mutual movement of the adjacent regions by the cured resin.

3. The method according to claim 1,
wherein the cut grooves comprise a plurality of cut grooves extending substantially in parallel and a plurality of cut grooves intersecting at least one of the parallel cut grooves, and the resin is disposed in a position of the intersection points of the cut grooves.

4. The method according to claim 1,
wherein the cut grooves comprise a plurality of cut grooves extending substantially in parallel and a plurality of cut grooves intersecting at least one of the cut grooves, and the resin is disposed in a position between the adjacent intersection points of the cut grooves.

5. The method according to claim 1,
wherein the plurality of regions include a plurality of rectangular regions, each of which has a semiconductor element formed thereon, and at least the resin is disposed at a pair of diagonally opposite corners in each of the rectangular regions.

6. The method according to claim 5,
wherein at least the resin is disposed at four corners of each of the rectangular regions.

7. The method according to claim 1,
wherein the plurality of regions include a plurality of rectangular regions, each of which has a semiconductor element formed thereon, and at least the resin is disposed at a side of each of the rectangular regions.

8. The method according to claim 1,
wherein the cutting in the step (f) is performed in a cutting width in the step (a).

9. The method according to claim 1,
wherein the resin which is disposed partly in the cut grooves is cut to remain partly on both side surfaces of the cut grooves at its disposed positions in the step (f).

10. The method according to claim 1,
wherein the step (b) includes injecting a liquid resin partly in the cut grooves and curing the injected resin as it is.

11. The method according to claim 10,
wherein the liquid resin has a viscosity (at 23° C.) of 4 Pa·s or more and has a modulus of elasticity (at 23° C.) of 0.2-5000 MPa after curing.

12. The method according to claim 10,
wherein the liquid resin has a viscosity (23° C.) of 9-21 Pa·s and has a modulus of elasticity (23° C.) of 10-5000 MPa after its curing.

13. The method according to claim 10,
wherein the liquid resin is a thermosetting resin or a light curable resin.

14. The method according to claim 10,
wherein the liquid resin is an epoxy-based thermosetting resin.

15. A semiconductor device, comprising a semiconductor chip configured to provide a rectangular plan shape, the semiconductor chip having a semiconductor element disposed on a front surface thereof and an adhesive agent layer disposed on a rear surface thereof,
wherein a part of a side surface of the semiconductor chip is selectively coated with a resin.

16. The semiconductor device according to claim 15,
wherein a corner of the semiconductor chip is coated with the resin.

17. The semiconductor device according to claim 15,
wherein a pair of diagonally opposite corners of the semiconductor chip are coated with the resin.

18. The semiconductor device according to claim 15,
wherein four corners of the semiconductor chip are coated with the resin.

19. The semiconductor device according to claim 15,
wherein a side of the rectangular semiconductor chip is coated with the resin.

20. A semiconductor device, configured to be manufactured by a method, the method comprising:
(a) forming cut grooves in a front surface of a semiconductor wafer on which semiconductor elements are formed to partition the front surface into a plurality of regions;
(b) disposing partly a resin in the cut grooves;
(c) adhering a protection tape on the front surface of the semiconductor wafer;
(d) thinning the semiconductor wafer by grinding a rear surface of the semiconductor wafer to reach the cut grooves;
(e) forming an adhesive agent layer on the rear surface of the semiconductor wafer; and
(f) dividing the semiconductor wafer into a plurality of semiconductor chips by cutting the adhesive agent layer together with the disposed resin along the cut grooves.
